(19) United States
(12) Patent Application Publication
(10) Pub. No.: US 2014/0049881 A1
(43) Pub. Date: Feb. 20, 2014

(54) Electrical Equipment Cabinet Having Improved Thermal Characteristics and Cable Management

(71) Applicants: Deborah A. Chambers, Asheville, NC (US); Ian J. Timmins, (US); Sumio Seo, (US); James Yanik, (US); Deborah A. Chambers, (US); Sterling A. Vaden, (US)

(72) Inventors: Ian J. Timmins, Asheville, NC (US); Sumio Seo, Wallingford, VT (US); James Yanik, Asheville, NC (US); R. Bruce Smith, Asheville, NC (US); Sterling A. Vaden, Black Mountain, NC (US)

(73) Assignee: Optical Cable Corporation, Roanoke, VA (US)

(21) Appl. No.: 13/764,333

(22) Filed: Feb. 11, 2013

Related U.S. Application Data
(60) Provisional application No. 61/597,221, filed on Feb. 10, 2012.

(51) Int. Cl. H05K 5/02

(52) U.S. Cl. CPC H05K 5/0213
USPC 361/679.01; 165/135

(57) ABSTRACT

An electrical equipment cabinet encloses a rack supporting equipment and cables connected to the electrical equipment. The rack and the cabinet define a gap between the rack and at least one side wall of the cabinet. The cabinet includes a thermal barrier fitting within the gap and defining a channel for cables. The thermal barrier includes a bracket connecting to the cabinet a channel side wall extending from the bracket, and a hinged panel connected to the channel side wall. The equipment cabinet may utilize a plurality of the thermal barriers to eliminate warm air bypass routes within the cabinet that deteriorate the cooling effect of air blowing across the equipment from front to back of the cabinet. Temperatures sensors and fens may be incorporated into the cabinet for additional temperature control. The thermal barriers and the control system may be part of a kit used retrofit existing cabinets.

### CROSS REFERENCE TO RELATED APPLICATIONS

This application claims priority to U.S. Provisional Patent Application Ser. No. 61/597,221 filed on Feb. 10, 2012, the entirety of which is incorporated herein by reference.

### BACKGROUND

An electrical equipment cabinet houses electrical equipment such as servers, routers, network switches, and patch panels which are received on shelves forming part of a rack that holds the equipment. This equipment is normally rectangular in shape and is able to slide in and out of the rack in the cabinet. Some of this equipment, in particular servers, consumes a substantial amount of electrical energy. Multiple servers in a cabinet have been known to consume over ten kilowatts, and it is anticipated that future systems will consume as much as one hundred kilowatts. This energy consumption generates a substantial amount of heat within the cabinet. Since the cabinet is somewhat closed it is important to dissipate the heat, otherwise the electrical equipment and components can be damaged.

FIG. 1 shows a prior art equipment cabinet (10) in which the equipment rack (16) and the side walls (18, 20) of the equipment cabinet (10) define open gaps (12,14) within the cabinet and between the rack and the side walls. These open gaps affect the air flow into and out of the cabinet and therefore affect the heat dissipation within the cabinet. As shown in FIG. 1, cooling air (38) enters the cabinet from the bottom of the cabinet (10) and should exit through the rear of the cabinet near the cabinet top (19) as shown by the exiting air flow (39). The exiting air (39) promotes a cooling effect on the electrical equipment in the cabinet. Unfortunately, the gaps (12, 14) in the equipment cabinets simultaneously provide a warm air bypass (46A, 46B) on either side of the rack (16). As a result warm air from the bypasses (46A, 46B) moves through the gaps (12, 14) in the cabinet and heat the cooling air (38). This prior art air flow is shown also in FIG. 4. The gaps (12, 14), therefore, increase the air temperature inside the cabinet and significantly deteriorate the efficiency of the cooling air system.

### BRIEF SUMMARY OF THE INVENTION

In one embodiment, a thermal barrier seals an open gap region extending along the sides of an equipment cabinet enclosing a rack. The thermal barrier attaches to the equipment cabinet via a bracket that connects to the equipment rack. The thermal barrier has at least one barrier side section extending from the bracket and a panel connected to the barrier side section with a hinge, wherein the bracket, the barrier side section, and the panel define a channel.

In a different embodiment, an equipment cabinet enclosing a rack supports electrical equipment and cables connected to the electrical equipment. The rack and the cabinet define a gap between the rack and a side wall of the cabinet. The equipment cabinet includes at least one thermal barrier fitting within the gap and defining a first channel for cables extending from the rack. The thermal barrier includes a bracket connecting to the cabinet, a channel side wall extending from the bracket, and a panel connected to the channel side wall by a hinge such that the panel swings between an open and closed position.

### BRIEF DESCRIPTION OF THE FIGURES

FIG. 1 is a front elevation view of a prior art equipment cabinet with thermal bypass gaps on either side.

FIG. 2 is an exploded view of an equipment cabinet with thermal barriers as set forth herein.

FIG. 3 is a front view of an equipment cabinet with thermal barriers as set forth herein.

FIG. 4 is a top cross section view of a prior art equipment cabinet of the prior art with thermal bypass gaps on either side.

FIG. 5 is a top cross section view of an equipment cabinet as set forth herein with thermal barriers installed therein.

FIG. 6 is a trout elevation view of an equipment cabinet as set forth herein with thermal harriers installed therein.

FIG. 7 is a perspective view of an interior of an equipment cabinet as set forth herein.

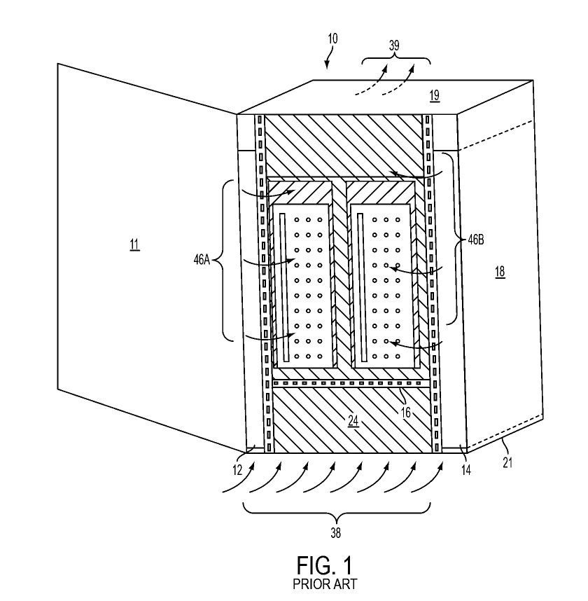

### DETAILED DESCRIPTION

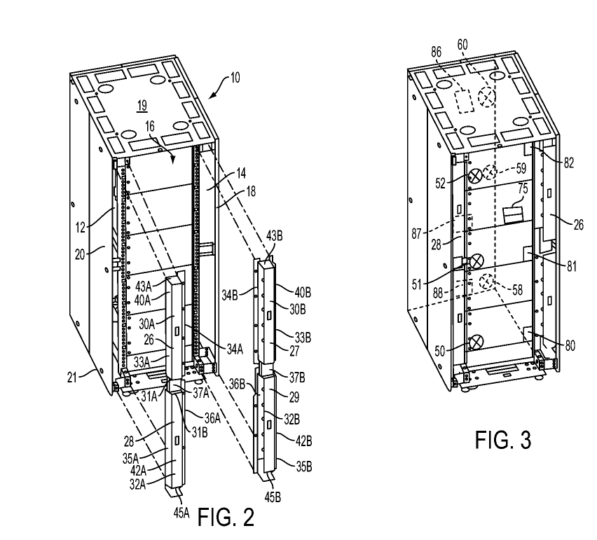

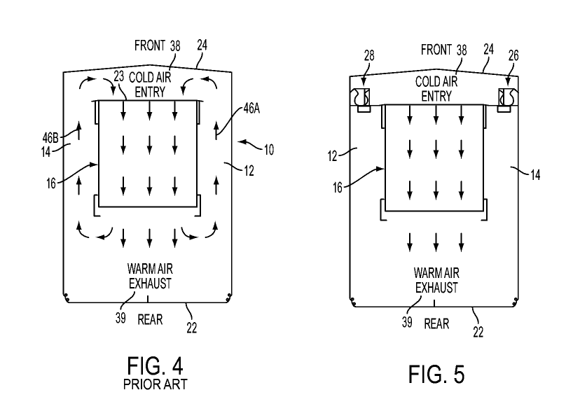

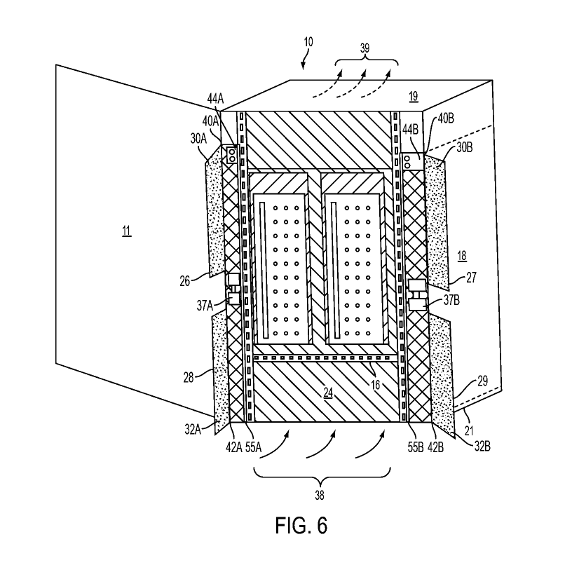

FIG. 2 shows an exploded view of an equipment cabinet (10) incorporating a rack (16) for holding electrical equipment thereon and to enclose the equipment in a safe and secure manner. The equipment cabinet (10) includes thermal barriers (26, 28) for sealing the open gap regions (12,14) extending along the side walls (18, 20) of the equipment cabinet (10). In one embodiment, the gaps (12, 14) extend in a predominantly vertical direction from the top (19) to the bottom (21) of the cabinet (10). The thermal barriers (26, 27, 28, 29) may be inserted into or removed from the cabinet (10), as at least a portion of the thermal barriers fits within the gaps (12, 14) defined between the rack (16) in the cabinet and the side walls (18, 20) of the cabinet. In one embodiment, the thermal barriers (26, 27, 28, 29) fit entirely within the gaps (12, 14) such that the thermal barriers (26, 27, 28, 29) are flush with a front (24) of the cabinet (10) as shown in FIG. 3. In other embodiments that do not limit the scope of the invention disclosed herein, the thermal barriers (26, 27, 28, 29) may be recessed within the gaps (12, 14) or have a portion that protrudes from the gaps. In any embodiment, the thermal barriers (26, 27, 28, 29) minimize the warm air bypass routes (46A, 46B) that deteriorate the cooling ventilation available in the cabinet (10). FIG. 5 shows a schematic embodiment of the air flow that moves from front to back in a cabinet without the complicating factor of the warm air bypass routes (46A, 46B) that are present in the prior art cabinets having unobstructed gaps (12, 14). FIG. 6 shows the thermal barrier installations in an overall equipment cabinet and illustrates that the cold air input (38) results in a comparable warm air output (39) for cooling the interior of the cabinet (10).

In the embodiment of FIG. 2, the thermal barriers (26, 27, 28, 29) are mirror images of each other and fit within gaps (12, 14) on opposite sides of the cabinet (10) as shown in FIG. 3. The exploded view of FIG. 2 depicts the thermal barriers (26, 27, 28, 29) as not only blocking the warm air bypasses (46A, 46B) within the cabinet (10), but the thermal barriers (26, 27, 28, 29) also define channels (31A, 31B) or void spaces encompassed by the respective bodies of the thermal barriers (26, 27, 28, 29). The channels are formed within the body of each thermal barrier and are defined by the respective spatial regions interior to a bracket (34A, 34B, 36A, 36B), at least one barrier side section (33A, 33B, 35A, 35B), and a panel (30A, 30B, 32A, 32B). In other words, the thermal barriers (26, 27, 28, 29) may define a hollow region, or channel (31) through which electrical cables (48) from equipment on the rack (16) may extend. The channels (31A, 31B) may be enclosed at ends of the thermal barrier by a top tab (43A, 43B) and a bottom tab (45A, 45B).

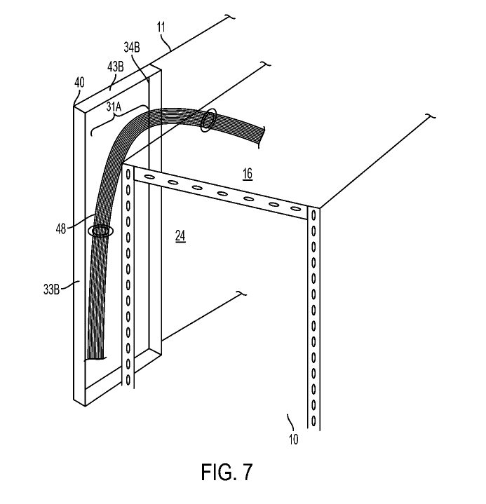

The channel formed by a thermal barrier (26, 27, 28, 29) is accessible due to the front panel (30A, 30B, 32A, 32B) being attached to the bracket (34A, 34B, 36A, 36B) by a hinge (40A, 40B, 42A, 42B) that allows the front panel to be optionally opened or closed. This arrangement allows the cables (48) extending from the rack (16) to be examined or at least accessed through the thermal barrier (26, 27, 28, 29). The channel may be entirely enclosed when the thermal barrier includes an opposite side section also extending from any one of the brackets parallel to the at least one barrier side section (33A, 33B, 35A, 35B). In other words, the channel may be enclosed by the bracket, two side sections, and a hinged panel that opens and closes. The cables running through the above noted channel may also extend through respective openings in the brackets that may be covered and not passable due to removable plugs (44A, 44B) shown best in FIG. 6. FIG. 7 shows an example of cables (48) extending from a rack (16) into a channel (31A) defined by a thermal barrier as described herein.

The thermal barriers may be connected to one another to extend along the entirety of a gap (12, 14) that runs along the entire height of an equipment cabinet (10). In one embodiment a plate (37) connects a lower end of one thermal barrier (26, 27) to an upper end of a different thermal barrier (28, 29). Without limiting the scope of structures that may be considered to be thermal barriers, therefore, an overall thermal barrier, also referred to as a bypass block, may be described as a combination of two or more individual thermal barriers that connect together to entirely fill a gap (12, 14) running from top (19) to bottom (21) of an equipment cabinet (10). Accordingly, a thermal barrier or warm air bypass block extending from a top tab (43A, 43B) to a bottom tab (45A, 45B) may include a bracket (34A), at least one barrier side section (33A) extending from the bracket, a panel (30A) connected by a hinge (40A) to the barrier side section (33A), a second bracket (36A) that connects to the equipment rack (16) and connects to the bracket (34A) by a connecting plate (37A) such that the bracket (33A) and the second bracket (36A) are aligned to extend along one side of the equipment cabinet (10). The overall thermal barrier or warm air bypass block further includes a second barrier side section (35A) extending from the second bracket (36A) and a second panel (32A) connected to the second barrier side section (35A) with a second hinge (42A), wherein the second bracket (36A), the second barrier side section (35A), and the second panel (32A) define a second channel (31A) that is aligned with a first channel (31A) formed by the bracket (34A), barrier side section (33A) extending from the bracket, and the panel (30A) connected by a hinge (40A) to the barrier side section (33A).

In a different embodiment, the thermal barrier may be described as one part of an overall equipment cabinet (10) enclosing a rack (16) supporting electrical equipment and cables (48) connected to the electrical equipment, wherein the rack (16) and die cabinet (10) define a gap (12, 14) between the rack and a side wall (18, 20) of the cabinet. The equipment cabinet (10) includes the above described thermal barriers. At least one thermal barrier (26, 27, 28, 29) fits within the defined gap and creates a first channel (31A, 31B) for cables extending from the rack to pass through the cabinet. Similar to the above noted descriptions, the thermal barrier may include a bracket (34A, 34B, 36A, 36B) connecting to the cabinet, a channel side wall (33A, 33B, 35A, 35B) extending from the bracket, and a panel (30A, 30B, 32A, 32B) connected to the channel side wall by a hinge (40A, 40B, 42A, 42B) such that the panel swings between an open and closed position. An opposite channel side wall extends from the bracket substantially parallel to the channel side wall and a latching mechanism, such as a hook and loop strip combination (FIG. 6—55A, 55B) connects to the opposite channel side wall for temporarily attaching the panel to the opposite channel side wall.

Similar to the aligned thermal barriers (26) noted above, an equipment cabinet (10) disclosed herein may include a second thermal barrier (28) having a second bracket (36A) that connects to the equipment rack and connects to the bracket (34A) by a connecting plate (37A) such that the bracket and the second bracket are aligned to extend along one side of the equipment cabinet. A second barrier side section (35A) extends from the second bracket (36A), and a second panel (32A) connects to the second barrier side section with a second hinge (42A), wherein the second bracket, the second barrier side section, and the second panel define a second channel (31B) that is aligned with a first channel (31A) of the connected thermal barrier (26). The channels may be fully enclosed by the addition of a second opposite channel side wail extending from the bracket and the second bracket substantially parallel to the second channel side section. Finally, a second latching mechanism, such as a pair of hook and loop strips, connects to the second opposite channel side wail for temporarily attaching the second panel to the second opposite channel side wall.

The overall equipment cabinet (10) may have at least four thermal barriers connected as appropriate to provide a warm air bypass block that increases the cooling efficiency of the cabinet (10). In one embodiment, a third thermal barrier (27) fits within a second gap (14) defined by the rack and an opposite side wall of the cabinet (18). The third thermal barrier includes a third bracket (34B) that connects to the equipment cabinet (10), a third barrier side section (33B) extending from the third bracket, a third panel (30B) connected to the third barrier side section with a third hinge (40B), wherein the third bracket, the third barrier side section, and the third panel define a third channel that is substantially parallel to channels (31A, 31B) on an opposite side of the equipment cabinet (10). This embodiment may include a third opposite channel side wall extending from the third bracket substantially parallel to the third channel side section (33B) and a third latching mechanism, such as hook and loop strips connected to the third opposite channel side wall for temporarily attaching the third panel (30B) to the third opposite channel side wall.

In accordance with the above noted three thermal barriers, a fourth thermal barrier (29) also fits within the second gap (14) defined by the rack (16) and an opposite side wall (18) of the cabinet. The fourth thermal barrier includes a fourth bracket (36B) that connects to the equipment cabinet, a fourth barrier side section (42B) extending from the fourth bracket, and a fourth panel (32B) connected to the fourth barrier side section with a fourth hinge (42B), wherein the fourth bracket, the fourth barrier side section, and the fourth panel define a fourth channel that is substantially parallel to channels (31A, 31B) defined on the opposite side of the cabinet (10) and aligned with a channel formed by a connected thermal barrier (26). This embodiment may include a fourth opposite channel side wall extending from the fourth bracket and a fourth latching mechanism connected to the fourth opposite channel side wall for temporarily attaching the fourth panel to the fourth opposite channel side wall.

The invention may also include components suitable for integration into any existing cabinet, whereby these components may be comprised of sensors, microcontrollers, fans and ducting equipment to enable a passive cabinet with, the general abilities of the thermal barrier disclosed above along with a control system for modulating the temperature inside the cabinet (10). In this embodiment, shown by example in FIG. 3, the cabinet (10) may include a first plurality of sensors detecting the respective temperatures at bottom (80), middle (81), and top (82) positions along a front region (24) of the equipment cabinet. The cabinet may also include a second plurality of sensors detecting the respective temperatures of bottom (86), middle (87) and top (88) positions along a rear region (22) of the equipment cabinet (10). The equipment cabinet may also house a plurality of fans (50, 51, 52) positioned respectively along the bottom, middle, and top portions of the front region (24) of the cabinet as well, as similar fans (58, 59, 60) positioned in the rear (22) of the equipment cabinet. All of the sensors and fans may be controlled by a controller (75) to direct air flow through the equipment cabinet. The sensors, the fens, and the controller may be networked to be in electrical data, communication with each other. The controller uses programmed commands (i.e., computerized software operating on a computer storage medium) to determine and set variables, such as fan speed, fan direction, air current direction, and the like for cooling the equipment, in the cabinet. The controller may include such useful features as an electronic display showing the status of numerous sensors, fans, and other equipment that is useful in the cooling system.

The above noted features of the equipment cabinet may be added to an existing prior art cabinet, such that the overall cooling system including numerous thermal barriers and associated hardware, the fans, the sensors, and the communications network components for controlling the same form a separate product kit design for retrofitting existing cabinets.

From the foregoing description of one embodiment of the invention, it will be apparent that many modifications may be made therein. It will be understood that this embodiment of the invention is an exemplification of the invention only and that the invention is not limited thereto.

1. A thermal barrier for sealing open gap regions extending along the sides of an equipment cabinet enclosing a rack, the thermal barrier comprising:
a bracket that connects to the equipment rack;
at least one barrier side section extending from said bracket;
a panel connected to said barrier side section with a hinge, wherein said bracket, said barrier side section, and said panel define a channel.

2. A thermal barrier according to claim 1, wherein said thermal barrier fits within one of the open gap regions to seal the gap region.

3. A thermal barrier according to claim 1, wherein the open gap region extends from a top of the equipment cabinet to a bottom of the equipment cabinet alongside the enclosed rack, and the thermal barrier fits within the open gap such that said panel is flush with a front of the equipment cabinet.

4. A thermal barrier according to claim 1, further comprising a top tab connected said bracket and covering the channel.

5. A thermal barrier according to claim 1, further comprising a bottom tab covering an opposite end of the channel.

6. A thermal barrier according to claim 1, further comprising:
a second bracket that connects to the equipment rack and connects to the bracket by a connecting plate such that said bracket and said second bracket are aligned to extend along one side of the equipment cabinet;
a second barrier side section extending from said second bracket;
a second panel connected to said second barrier side section with a second hinge, wherein said second bracket, said second barrier side section, and said second panel define a second channel that is aligned with the first channel.

7. A thermal barrier according to claim 1, further comprising:
at least one opposite side section extending from said bracket;
a latching mechanism for temporarily securing said panel to said opposite side section in a closed position.

8. A thermal barrier according to claim 1, further comprising a removable plug connected to said bracket for allowing or disallowing access through an opening in the bracket defined by said removable plug.

9. An equipment cabinet enclosing a rack supporting electrical equipment and cables connected to the electrical equipment, wherein the rack and the cabinet define a gap between the rack and a side wall of the cabinet, the cabinet comprising:
at least one thermal barrier fitting within the gap and defining a first channel for cables extending from the rack, wherein the thermal barrier comprises a bracket connecting to the cabinet, a channel side wall extending from die bracket, and a panel connected to the channel side wall by a hinge such that said panel swings between an open and closed position.

10. An equipment cabinet according to claim 9, further comprising:
an opposite channel side wall extending from said bracket substantially parallel to said channel side wall;
a latching mechanism connected to said opposite channel side wall for temporarily attaching said panel to said opposite channel side wall.

11. An equipment cabinet according to claim 9, further comprising:
a second thermal barrier comprising a second bracket that connects to the equipment rack and connects to the bracket by a connecting plate such, that said bracket and said second bracket are aligned to extend along one side of the equipment cabinet;
a second barrier side section extending from said second bracket;
a second panel connected to said second barrier side section with a second hinge, wherein said second bracket, said second barrier side section, and said second panel define a second channel that is aligned with the first channel.

12. An equipment cabinet according to claim 11, further comprising:
a second opposite channel side wall extending from said second bracket substantially parallel to said second channel side section;
a second latching mechanism connected to said second opposite channel side wall for temporarily attaching said second panel to said second opposite channel side wall.

13. An equipment cabinet according to claim 11, further comprising:
a third thermal barrier that fits within a second gap defined by the rack and an opposite side wall of the cabinet, said third thermal barrier comprising:
a third bracket that connects to the equipment cabinet;
a third barrier side section extending from said third bracket; and
a third panel connected to said third barrier side section with a third hinge, wherein said third bracket, said third barrier side section, and said third panel define a third channel that is substantially parallel to the first channel.

14. An equipment cabinet according to claim 13, further comprising:
a third opposite channel side wall extending from said third bracket substantially parallel to said third channel side section;
a third latching mechanism connected to said third opposite channel side wall for temporarily attaching said third panel to said third opposite channel side wall.

15. An equipment cabinet according to claim 13, further comprising:
a fourth thermal barrier that tits within the second gap defined by the rack and an opposite side wall of the cabinet, said fourth thermal barrier comprising:
a fourth bracket that connects to the equipment cabinet;
a fourth barrier side section extending from said fourth bracket; and
a fourth panel connected to said fourth barrier side section with a fourth hinge, wherein said fourth bracket, said fourth barrier side section, and said fourth panel define a fourth channel that is substantially parallel to the second channel and aligned with the third channel.

16. An equipment cabinet according to claim 15, further comprising:
a fourth opposite channel side wall extending from said fourth bracket substantially parallel to said second channel side section;
a fourth latching mechanism connected to said fourth opposite channel side wall for temporarily attaching said fourth panel to said fourth opposite channel side wall.

17. An equipment cabinet according to claim 9, further comprising a first plurality of sensors detecting the respective temperatures at bottom, middle, and top positions along a front region of the equipment cabinet.

18. An equipment cabinet according to claim 17, further comprising a second plurality of sensors detecting the respective temperatures of bottom, middle and top positions along a rear region of the equipment cabinet.

19. An equipment cabinet according to claim 18, further comprising a controller in electrical communication with said first and second plurality of sensors.

20. An equipment cabinet according to claim 19, further comprising a plurality of fans positioned in the equipment cabinet and controlled by said controller to direct air flow through the equipment cabinet.
